(19) United States
(12) Patent Application Publication
(10) Pub. No.: US 2023/0343505 A1
(43) Pub. Date: Oct. 26, 2023

(54) MAGNETIC ELEMENT AND CIRCUIT BOARD INCLUDING SAME

(71) Applicant: LG INNOTEK CO., LTD., Seoul (KR)

(72) Inventors: Yong Hwan KIM, Seoul (KR); Yu Seon KIM, Seoul (KR); Seok BAE, Seoul (KR)

(21) Appl. No.: 18/022,327

(22) PCT Filed: Aug. 26, 2021
(86) PCT No.: PCT/KR2021/011422

§ 371 Date: Feb. 21, 2023

(30) Foreign Application Priority Data
Aug. 26, 2020 (KR) 10-2020-0108017

(51) Int. Cl. H01F 27/28; H01F 17/00; H05K 1/16

(52) U.S. Cl. CPC H01F 27/2804; H01F 17/0006; H05K 1/165; H01F 2017/0073

(57) ABSTRACT

The present invention relates to a magnetic coupling device that can become slim and a circuit board including same. A magnetic coupling device according to one embodiment of the present invention comprises: a core unit including an upper core and a lower core; and a coil unit of which a part is arranged in the core unit, and which includes a first coil unit and a second coil unit, wherein the first coil unit and the second coil unit have a substrate and conductive patterns arranged on both surfaces of the substrate, and the conductive patterns on both surfaces can be conducted through a plurality of via holes arranged in the extending direction of the conductive patterns.

### TECHNICAL FIELD

The present disclosure relates to a magnetic element having a reduced thickness and a circuit board including the same.

### BACKGROUND ART

A magnetic element may alternatively be referred to as a magnetic coupling device, and representative examples thereof may include an inductor, a transformer, and an EMI filter in which an inductor and a capacitor are connected to each other. Such a magnetic element may be mounted on any of various types of circuit boards.

As electronic products have recently become slimmer, a slim-type magnetic element, in which coils constituting the magnetic element have a form of a printed circuit board (PCB) and share a center leg of a magnetic core, is widely used. This will be described with reference to FIG. 1.

FIG. 1 shows an example of the configuration of a general magnetic element.

Referring to FIG. 1, a magnetic element may include a core unit 10 and a coil unit 20. The core unit 10 may include an upper core 11 and a lower core 12, and the coil unit 20, which is of a printed circuit board (PCB) type, is disposed between the upper core 11 and the lower core 12.

The coil unit 20 is configured such that conductive patterns forming a plurality of turns are disposed on the upper surface, the lower surface, or both surfaces of a substrate to function as coils. However, the conductive patterns have a problem of increase in resistance due to the skin effect. In particular, when the conductive patterns are disposed on both surfaces of a single substrate, there is a problem in that large loss may occur due to the proximity effect between the conductive patterns. This problem may be solved to some extent by increasing the thicknesses of the conductive patterns. However, because the conductive patterns are generally formed of copper, the increase in thickness leads to increase in cost of manufacturing the magnetic element, and the thicknesses of the patterns that can be formed on the substrate are also restricted.

### DISCLOSURE

### Technical Problem

A technical task of the present disclosure is to provide a slim-type magnetic coupling device, which has a further reduced thickness and reduces loss due to a resistance component of a coil, and a circuit board using the same.

The technical tasks of the present disclosure are not limited to the above-mentioned technical tasks, and other technical tasks not mentioned herein will be clearly understood by those skilled in the art from the following description.

### Technical Solution

A magnetic coupling device according to an embodiment may include a core unit including an upper core and a lower core and a coil unit partially disposed inside the core unit and including a first coil unit and a second coil unit. The first coil unit may include a first substrate, a first upper conductive pattern disposed on the upper surface of the first substrate, and a first lower conductive pattern disposed on the lower surface of the first substrate, and the second coil unit may include a second substrate, a second upper conductive pattern disposed on the upper surface of the second substrate, and a second lower conductive pattern disposed on the lower surface of the second substrate. Each of the first upper conductive pattern and the first lower conductive pattern may have a first spiral planar pattern, which circles in a first direction, and each of the second upper conductive pattern and the second lower conductive pattern may have a second spiral planar pattern, which circles in a second direction. The first upper conductive pattern and the first lower conductive pattern may be conductively connected to each other through a plurality of first via holes penetrating the first substrate in a vertical direction and disposed in an extension direction of the first spiral planar pattern, and the second upper conductive pattern and the second lower conductive pattern may be conductively connected to each other through a plurality of second via holes penetrating the second substrate in the vertical direction and disposed in an extension direction of the second spiral planar pattern.

In an example, the coil unit may include a turn portion in which each of the first upper conductive pattern, the first lower conductive pattern, the second upper conductive pattern, and the second lower conductive pattern forms a plurality of turns and a pattern lead-out portion in which one end of each of the first upper conductive pattern, the first lower conductive pattern, the second upper conductive pattern, and the second lower conductive pattern is led out from the central portion, the pattern lead-out portion being disposed on one side of the turn portion.

In an example, opposite ends of the first upper conductive pattern, the first lower conductive pattern, the second upper conductive pattern, and the second lower conductive pattern may be conductively connected to each other, the opposite ends being disposed at an innermost position in the turn portion.

In an example, the turn portion may include a central portion wrapped by the core unit and outer portions disposed on both sides of the central portion. Among the plurality of first via holes and the plurality of second via holes, the number of via holes per unit length in the central portion may be greater than the number of via holes per unit length in the outer portions.

In an example, the plurality of second via holes may be disposed in the turn portion in an extension direction of the second spiral pattern at an interval corresponding to ⅒ or less of the length of the second upper conductive pattern in the long-axis direction of the turn portion.

In an example, the plurality of second via holes may be disposed in the turn portion in the extension direction of the second spiral pattern at an interval corresponding to 1/20 or less of the length of the second upper conductive pattern in the long-axis direction of the turn portion.

In an example, the plurality of first via holes and the plurality of second via holes may have radial planar shapes in a manner of being aligned in a centrifugal direction from a center leg of the core unit.

In an example, the coil unit may further include a third coil unit and a fourth coil unit, which at least partially overlap the first coil unit and the second coil unit in the vertical direction.

In an example, the third coil unit may be disposed in a manner of being rotated by 180 degrees relative to the first coil unit when viewed in a plan view, and the fourth coil unit may be disposed in a manner of being rotated by 180 degrees relative to the second coil unit when viewed in a plan view.

A circuit board according to an embodiment may include a substrate and a magnetic coupling device disposed on the circuit board, wherein the magnetic coupling device may include a core unit including an upper core and a lower core and a coil unit partially disposed inside the core unit and including a first coil unit and a second coil unit. The first coil unit may include a first substrate, a first upper conductive pattern disposed on the upper surface of the first substrate, and a first lower conductive pattern disposed on the lower surface of the first substrate, and the second coil unit may include a second substrate, a second upper conductive pattern disposed on the upper surface of the second substrate, and a second lower conductive pattern disposed on the lower surface of the second substrate. Each of the first upper conductive pattern and the first lower conductive pattern may have a first spiral planar pattern, which circles in a first direction, and each of the second upper conductive pattern and the second lower conductive pattern may have a second spiral planar pattern, which circles in a second direction. The first upper conductive pattern and the first lower conductive pattern may be conductively connected to each other through a plurality of first via holes penetrating the first substrate in a vertical direction and disposed in an extension direction of the first spiral planar pattern, and the second upper conductive pattern and the second lower conductive pattern may be conductively connected to each other through a plurality of second via holes penetrating the second substrate in the vertical direction and disposed in an extension direction of the second spiral planar pattern.

### Advantageous Effects

The magnetic coupling device according to the embodiment is configured such that conductive patterns having the same planar shape as each other are disposed on both surfaces of a single substrate and are conductively connected to each other through via holes penetrating the substrate, thereby exhibiting an effect of increasing the effective thickness of the overall conductive pattern.

Therefore, the skin effect and the proximity effect are reduced, and thus resistance components of the conductive patterns are reduced. Accordingly, loss is reduced, and consequently, the efficiency of the magnetic coupling device and the circuit board using the same is improved.

The effects achievable through the present disclosure are not limited to the above-mentioned effects, and other effects not mentioned herein will be clearly understood by those skilled in the art from the following description.

### DESCRIPTION OF DRAWINGS

FIG. 1 shows an example of the configuration of a general magnetic element.

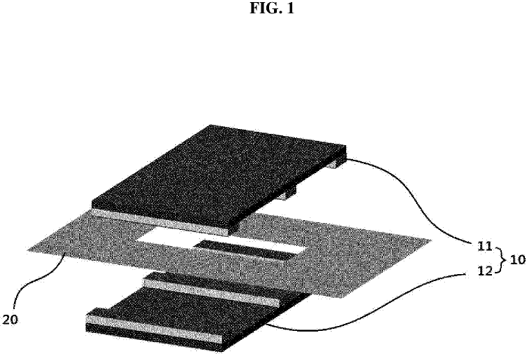

FIG. 2 is a perspective view of an inductor according to an embodiment.

FIG. 3 is an exploded perspective view of the inductor according to the embodiment.

FIG. 4 shows an example of the configuration of a first coil unit according to an embodiment.

FIG. 5 shows an example of the configuration of a second coil unit according to an embodiment.

FIG. 6 is a plan view for explaining via holes in the second coil unit according to an embodiment.

FIG. 7 shows an example of a via-hole configuration of the second coil unit according to another embodiment.

FIG. 8 is an exploded perspective view showing an example of the configuration of an inductor coil unit of an EMI filter according to an embodiment.

### BEST MODE

The present disclosure will now be described more fully hereinafter with reference to the accompanying drawings, in which various embodiments are shown. The examples, however, may be embodied in many different forms and should not be construed as being limited to the embodiments set forth herein. It is to be understood that the present disclosure covers all modifications, equivalents, and alternatives falling within the scope and spirit of the present disclosure.

While ordinal numbers including “second”, “first”, etc. may be used to describe various components, they are not intended to limit the components. These expressions are used only to distinguish one component from another component. For example, a second element could be termed a first element, and, similarly, a first element could be termed a second element, without departing from the scope of the present disclosure. As used herein, the term “and/or” includes any and all combinations of one or more of the associated listed items.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

In the description of the embodiments, it will be understood that when an element, such as a layer (film), a region, a pattern or a structure, is referred to as being “on” or “under” another element, such as a substrate, a layer (film), a region, a pad or a pattern, the term “on” or “under” means that the element is “directly” on or under another element or is “indirectly” formed such that an intervening element may also be present. It will also be understood that criteria of on or under is on the basis of the drawing. In addition, the thickness or size of a layer (film), a region, a pattern or a structure shown in the drawings may be exaggerated, omitted or schematically drawn for the clarity and convenience of explanation, and may not accurately reflect the actual size.

The terminology used herein is for the purpose of describing particular embodiments only and is not intended to be limiting of exemplary embodiments of the disclosure. As used herein, the singular forms are intended to include the plural forms as well, unless the context clearly indicates otherwise. It will be further understood that the term “include” or “have”, when used herein, specifies the presence of stated features, integers, steps, operations, elements, components, or combinations thereof, but do not preclude the presence or addition of one or more other features, integers, steps, operations, elements, components, or combinations thereof.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

Hereinafter, embodiments will be described in detail with reference to the accompanying drawings, and the same or equivalent elements are denoted by the same reference numerals even when they are depicted in different drawings, and redundant descriptions thereof will be omitted. In addition, some embodiments will be described using a coordinate system. In the coordinate system, a first axis, a second axis, and a third axis shown in each drawing are perpendicular to each other, but the embodiments are not limited thereto. The first axis, the second axis, and the third axis may intersect each other obliquely.

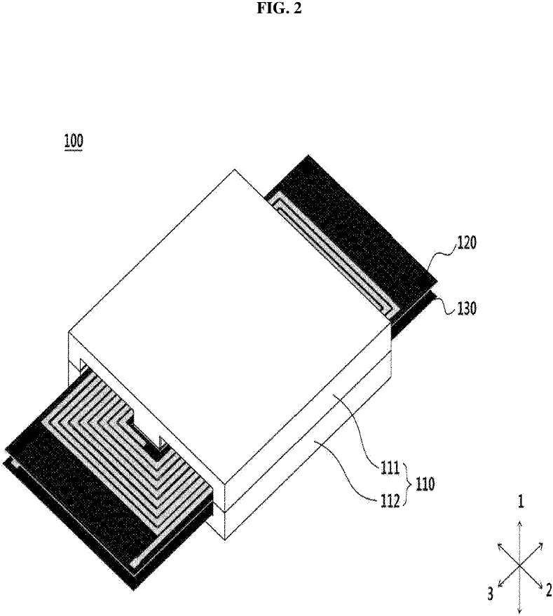

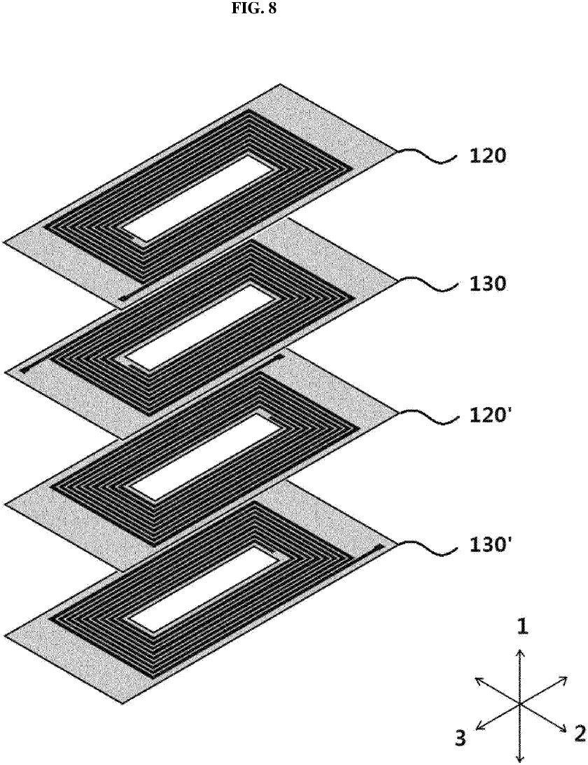

Hereinafter, a magnetic coupling device according to the embodiment will be described in detail with reference to the accompanying drawings. For convenience of description, FIGS. 2 to 7 illustrate an inductor as an example of the magnetic coupling device. However, the inductor is merely an example of the magnetic coupling device according to the embodiment, and the disclosure is not limited thereto. For example, as shown in FIG. 8, the magnetic coupling device according to the embodiment may be a component of an EMI filter, rather than being an inductor, or may be implemented as a transformer.

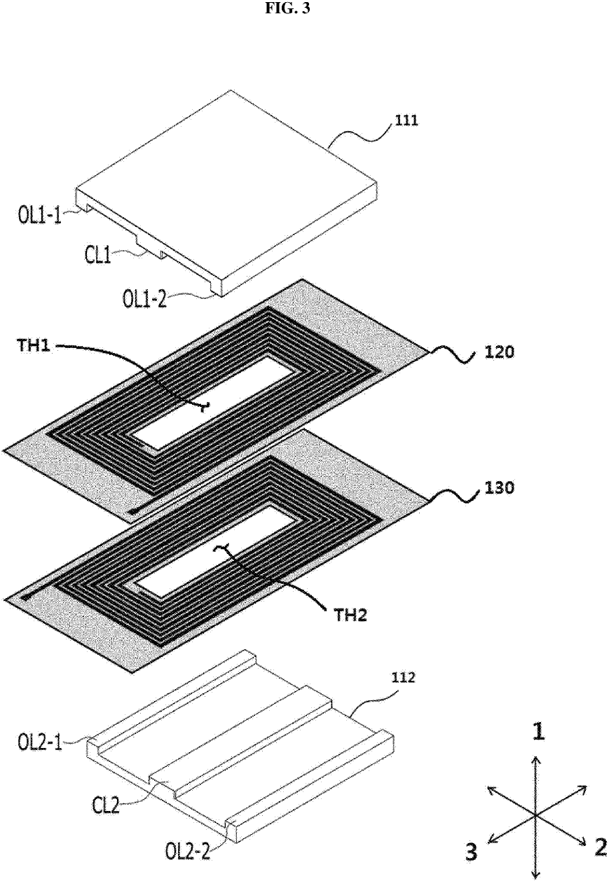

FIG. 2 is a perspective view of an inductor according to an embodiment, and FIG. 3 is an exploded perspective view of the inductor according to the embodiment.

Referring to FIGS. 2 and 3 together, an inductor 100 according to an embodiment may include a core unit 110 and coil units 120 and 130. Hereinafter, respective components will be described in detail.

The core units 111 and 112 may have the function of a magnetic circuit, and thus may serve as a path for magnetic flux. The core units 111 and 112 may include an upper core 111, which is disposed at an upper position, and a lower core 112, which is disposed at a lower position. The two cores 111 and 112 may be formed to be symmetrical or asymmetrical with each other in the vertical direction, or any one of the upper core 111 and the lower core 112 may be omitted. However, for convenience of explanation, the following description will be given on the assumption that the two cores are formed to be vertically symmetrical with each other.

Each of the upper core 111 and the lower core 112 may include a body portion, which has a flat plate shape, and a plurality of leg portions OL1-1, OL1-2, OL2-1, OL2-2, CL1, and CL2, which protrude from the body portion in a first direction (i.e. the first-axis direction) and extend in a predetermined direction. For example, the plurality of leg portions OL1-1, OL1-2, and CL1 of the upper core 111 may include two outer legs OL1-1 and OL1-2, which are disposed so as to be spaced apart from each other in a second direction (i.e. the second-axis direction), which intersects the first direction when viewed in a plan view, and one center leg CL1, which is disposed between the two outer legs OL1-1 and OL1-2. In addition, each of the plurality of leg portions OL1-1, OL1-2, OL2-1, OL2-2, CL1, and CL2 may extend in a third direction (i.e. the third-axis direction), which intersects the first and second directions when viewed in a plan view.

When the upper core 111 and the lower core 112 are coupled to each other in the vertical direction, each of the outer legs OL1-1 and OL1-2 and the center leg CL1 of the upper core 111 faces a corresponding one of the outer legs OL2-1 and OL2-2 and the center leg CL2 of the lower core 112. One pair of outer legs OL1-1 and OL2-1, which face each other, may be referred to as first outer leg portions, the other pair of outer legs OL1-2 and OL2-2, which face each other, may be referred to as second outer leg portions, and the pair of center legs CL1 and CL2, which face each other, may be referred to as center leg portions.

A gap having a predetermined distance (e.g. 10 to 200 µm, without being limited thereto) may be formed between at least one pair among the pairs of outer legs and the pair of center legs, which face each other. The sizes of the gaps between the one pair of center legs and between each of the two pairs of outer legs may be adjusted in order to control the inductance of the core unit 110, and the amount of heat that is generated may be controlled by varying the number of gaps.

In addition, the core unit 110 may include a magnetic material, for example, iron or ferrite, but the disclosure is not limited thereto.

Because the core unit 110 surrounds a portion of each of the coil units 120 and 130, it can be seen that a portion of each of a primary coil unit 120 and a secondary coil unit 130, which constitute the coil units 120 and 130, is disposed inside the core unit 110.

The primary coil unit 120 and the secondary coil unit 130 may respectively have a first through-hole TH1 and a second through-hole TH2 formed in the center portions thereof, and the center legs CL1 and CL2 of the core unit 110 may pass through the first through-hole TH1 and the second through-hole TH2. That is, when viewed in a plan view, the primary coil unit 120 and the secondary coil unit 130 may be aligned with each other around the center legs CL1 and CL2 passing through the first through-hole TH1 and the second through-hole TH2.

Each of the primary coil unit 120 and the secondary coil unit may be configured such that a conductive pattern is printed on each of the upper surface and the lower surface of a flat-plate-type substrate having a quadrangular planar shape so as to form a plurality of turns.

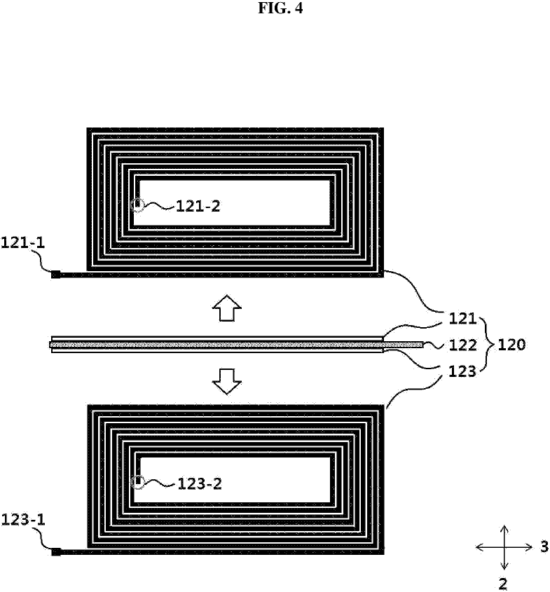

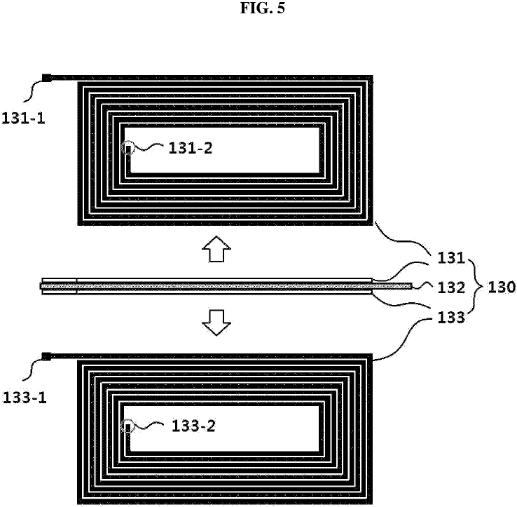

The configuration of the primary coil unit 120 and the secondary coil unit 130 will be described in more detail with reference to FIGS. 4 and 5.

FIG. 4 shows an example of the configuration of a first coil unit according to an embodiment.

In FIG. 4, the intermediate drawing is a side view of the first coil unit 120, the upper drawing is a plan view of a first upper conductive pattern 121, and the lower drawing is a plan view of a first lower conductive pattern 123.

Referring to FIG. 4, the first coil unit 120 may include a first substrate 122, a first upper conductive pattern 121 disposed on the upper surface of the first substrate 122, and a first lower conductive pattern 123 disposed on the lower surface of the first substrate 122.

Each of the first upper conductive pattern 121 and the first lower conductive pattern 123 may have a spiral planar shape, and may form a plurality of turns. The first upper conductive pattern 121 and the first lower conductive pattern 123 may have the same planar shape as each other (i.e. the directions in which the spiral patterns circle may be the same as each other), and may be aligned with each other in the vertical direction (the first-axis direction or the first direction) so as to overlap each other when viewed in a plan view. Since the first upper conductive pattern 121 and the first lower conductive pattern 123 have the same planar shape as each other, the description of the first upper conductive pattern 121 may also be applied to the first lower conductive pattern 123.

One end 121-1 of the first upper conductive pattern 121 is disposed on an edge portion of the substrate 122, and the other end 121-2 thereof is disposed at the innermost position in the spiral pattern. That is, the first upper conductive pattern 121 may extend from one end 121-1 thereof disposed on an edge portion of the substrate 122 in the long-axis direction of the substrate (i.e. the third direction), and then may extend to the other end 121-2 thereof in the inward direction from the outside while forming a spiral pattern.

FIG. 5 shows an example of the configuration of a second coil unit according to an embodiment.

Similar to the drawings in FIG. 4, in FIG. 5, the intermediate drawing is a side view of the second coil unit 130, the upper drawing is a plan view of a second upper conductive pattern 131, and the lower drawing is a plan view of a second lower conductive pattern 133.

Referring to FIG. 5, the second coil unit 130 may include a second substrate 132, a second upper conductive pattern 131 disposed on the upper surface of the second substrate 132, and a second lower conductive pattern 133 disposed on the lower surface of the second substrate 132.

Each of the second upper conductive pattern 131 and the second lower conductive pattern 133 may have a spiral planar shape, and may form a plurality of turns. The second upper conductive pattern 131 and the second lower conductive pattern 133 may have the same planar shape as each other (i.e. the directions in which the spiral patterns circle may be the same as each other), and may be aligned with each other in the vertical direction (the first-axis direction or the first direction) so as to overlap each other when viewed in a plan view. Since the second upper conductive pattern 131 and the first lower conductive pattern 133 have the same planar shape as each other, the description of the second upper conductive pattern 131 may also be applied to the second lower conductive pattern 133.

One end 131-1 of the second upper conductive pattern 131 is disposed on an edge portion of the substrate 132, and the other end 131-2 thereof is disposed at the innermost position in the spiral pattern. Here, the second upper conductive pattern 131 may extend from one end 131-1 thereof disposed on an edge portion of the substrate 132, and then may extend to the other end 131-2 thereof in the inward direction from the outside while forming a spiral pattern.

The first upper conductive pattern 121 and the first lower conductive pattern 123 may be conductively connected to each other through a plurality of via holes disposed in the extension direction of the spiral pattern. Here, the via hole may be a cylindrical conductive element that penetrates the first substrate 122 in the vertical direction (i.e. the first direction) to function as a passage for conductively connecting the first upper conductive pattern 121 and the first lower conductive pattern 123 to each other. Since the first upper conductive pattern 121 and the first lower conductive pattern 123, which have the same planar shape as each other, are conductively connected to each other through a plurality of via holes, the two conductive patterns 121 and 123 disposed on both surfaces of the first coil unit 120 form a single conductive pattern. Since the first upper conductive pattern 121 and the first lower conductive pattern 123 are connected to each other through a plurality of via holes, the effective thickness of the overall conductive pattern of the first coil unit 120 is greater than a sum of the thickness of the first upper conductive pattern 121 and the thickness of the first lower conductive pattern 123. On the basis of the principle that resistance is proportional to length and is inversely proportional to cross-sectional area, it is possible to obtain an effect of increase in effective cross-sectional area, because the two conductive patterns 121 and 123 are spaced apart from each other by a distance equivalent to the thickness of the first substrate 122 in the first direction but are connected to each other through a plurality of via holes. Consequently, the resistance of the first coil unit 120 may be lower than the resistance generated when the first upper conductive pattern 121 and the first lower conductive pattern 123 are connected in parallel.

Similar to the first coil unit 120, the second upper conductive pattern 131 and the second lower conductive pattern 133 of the second coil unit 120 may also be conductively connected to each other through a plurality of via holes disposed in the extension direction of the spiral pattern.

Meanwhile, the direction in which the spiral patterns of the first upper conductive pattern 121 and the first lower conductive pattern 123 circle and the direction in which the spiral patterns of the second upper conductive pattern 131 and the second lower conductive pattern 133 circle may be opposite each other. For example, the first upper conductive pattern 121 and the first lower conductive pattern 123 may have spiral patterns that circle from the ends 121-1 and 123-1 thereof to the other ends 121-2 and 123-2 thereof in the counterclockwise direction, and the second upper conductive pattern 131 and the second lower conductive pattern 133 may have spiral patterns that circle from the ends 131-1 and 133-1 thereof to the other ends 131-2 and 133-2 thereof in the clockwise direction.

Here, the other ends 121-2 and 123-2 of the first upper conductive pattern 121 and the first lower conductive pattern 123 and the other ends 131-2 and 133-2 of the second upper conductive pattern 131 and the second lower conductive pattern 132 may at least partially overlap each other when viewed in a plan view, and may be conductively connected to each other.

In the case in which the ends 131-2 and 133-1 of the second upper conductive pattern 131 and the second lower conductive pattern 133 are input terminals of current and the ends 121-1 and 123-1 of the first upper conductive pattern 121 and the first lower conductive pattern 123 are output terminals of current due to conductive connection between the other ends thereof and the spiral patterns that circle in opposite directions, the current flows consistently in one direction (i.e. the clockwise direction) in the coil units 120 and 130.

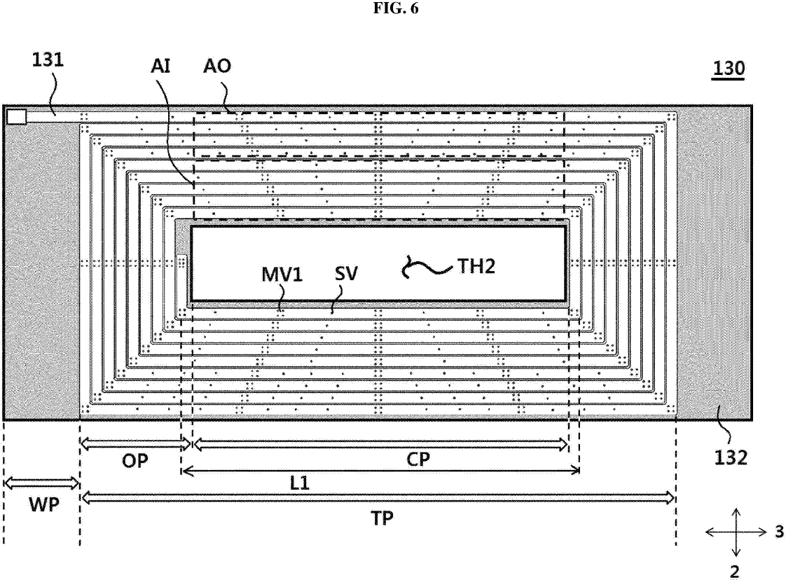

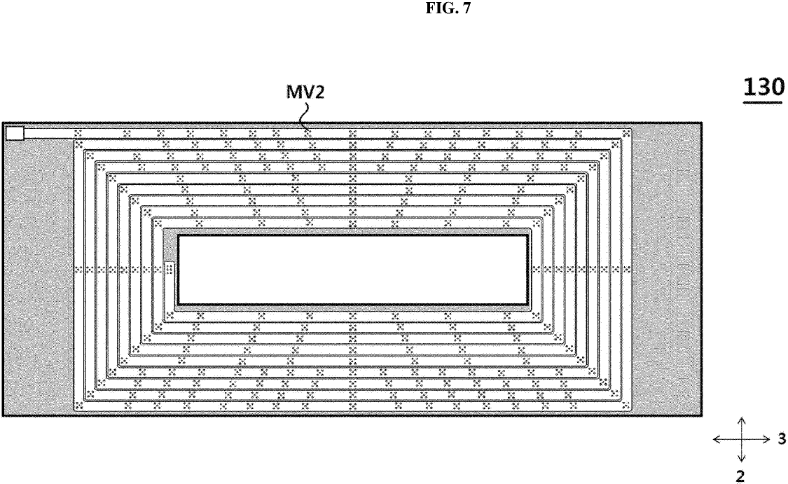

Hereinafter, disposition of via holes will be described with reference to FIGS. 6 and 7.

Disposition of a plurality of via holes in the second coil unit 130 will be described below on the assumption that the first coil unit 120 and the second coil unit 130 have mirror image shapes that are symmetrical with each other in the second direction.

FIG. 6 is a plan view for explaining via holes in the second coil unit according to an embodiment, and FIG. 7 shows an example of a via-hole configuration of the second coil unit according to another embodiment.

FIG. 6 illustrates a plan view of the second coil unit 130. In FIG. 6, the second lower conductive pattern 133 is hidden by the second substrate 132 and thus is not visible, but is aligned with the second upper conductive pattern 131 in the vertical direction.

When viewed in a plan view, the second coil unit 130 may include a turn portion TP, in which each of the conductive patterns 131 and 132 forms turns, and a pattern lead-out portion WP, which is located on one side of the turn portion TP in the long-axis direction of the second coil unit 130 (i.e. the third direction or the third-axis direction). That is, in the pattern lead-out portion WP, one end of each of the conductive patterns 131 and 132 may be led out from the turn portion TP in the third direction.

Meanwhile, when the inductor 100 is formed, the turn portion TP may include a central portion CP, which is wrapped by the core unit 110, and outer portions OP, which are disposed on both sides of the central portion CP in the third direction.

The number of via holes MV1 and SV per unit length in the central portion CP in the extension direction of the spiral pattern may be different from that in the outer portion OP. For example, the number of via holes per unit length in the central portion CP may be greater than the number of via holes per unit length in the outer portion OP. Because the current density in the central portion CP wrapped by the core unit 110 is higher than the current density in the outer portion OP, it is necessary to dispose a greater number of via holes in the central portion in order to lower a resistance value on the basis of the principle that increase in current density causes increase in resistance.

In addition, as shown in FIG. 6, when viewed in a plan view, the plurality of via holes MV1 and SV may be disposed so as to form a radial pattern in which the via holes are radially disposed and are aligned in the centrifugal direction from the center of the second coil unit, e.g. the second through-hole TH2 or the center leg of the core unit 110, toward the outside. Of course, this radial pattern is merely illustrative, and the plurality of via holes does not necessarily have a radial pattern when viewed in a plan view.

Different types of via holes MV1 and SV may be formed depending on the disposition positions thereof. For example, a single via hole SV may be disposed, or a via hole group MV1 in which a predetermined number of via holes (e.g. four via holes) is grouped may be disposed.

Referring to FIG. 6, the via hole groups MV1 are disposed in the center portion in the third direction, are disposed in both side portions in which the extension direction is changed to the second direction, and are disposed between the center portion and both side portions, and at least one single via hole SV is disposed between two adjacent ones of the via hole groups MV1. Alternatively, as shown in FIG. 7, via hole groups MV2 in each of which a predetermined number of via holes (e.g. five via holes) are grouped may be disposed over the entire area of the second coil unit.

In addition, the disposition interval between the via holes MV1 and SV in the extension direction of the spiral pattern may be determined depending on the length of each of the conductive patterns 131 and 133. Because resistance is proportional to the length of a conductor, it is necessary to prevent the interval between the via holes from exceeding a predetermined value. Therefore, the length L1 of the innermost portion of the pattern in the long-axis direction (i.e. the third direction) is longer than the length of the outermost portion of the pattern in the long-axis direction (corresponding to the length of “TP” in the third direction), and the resistance values of the respective portions of the conductive pattern gradually increase in a direction from the innermost portion thereof to the outermost portion thereof. Therefore, a greater number of via holes may be disposed in the outer area AO of the central portion CP than the inner area AI of the central portion CP.

Assuming that an operating frequency of 500 MHz is a high frequency in the case of a general PCB-type conductive pattern having specifications of 1 oz (i.e. a thickness of about 36 µm), via holes may be disposed at an interval corresponding to ⅒ or less of the length of the pattern in the third direction when the operating frequency is 500 MHz or less. For example, when the length L1 of the innermost portion of the pattern is 6 cm, the via holes may be disposed such that the interval between the via holes does not exceed 6 mm in the innermost portion of the conductive pattern. In the case of a conductive pattern having specifications of 2 oz, the resistance value thereof is about half that of a conductive pattern having specifications of 1 oz, and therefore the interval between via holes may be 1/20 or less of the length of the pattern in the third direction. Of course, this disposition interval between via holes may vary depending on the diameter thereof or the type of group thereof.

For example, when a target allowable current amount is set to 2.5 A such that an actual allowable current amount of each of the conductive patterns 131 and 133 having a thickness of 2 oz and a width of 1.4 mm is 2 A, via holes each having a diameter of 1.0 mm are formed on the basis of the above-described interval so that a current of 2 A actually passes through the conductive pattern. In this case, in order to obtain an effect equivalent to the effect achievable through the via holes each having a diameter of 1 mm, via hole groups in each of which five via holes each having a diameter of 0.1 mm are grouped may be disposed at an interval equivalent to 1/20 of the length of the pattern.

So far, the inductor has been described as an example of the magnetic coupling device according to the embodiment. Hereinafter, an EMI filter according to an embodiment will be described with reference to FIG. 8.

FIG. 8 is an exploded perspective view showing an example of the configuration of an inductor coil unit of an EMI filter according to an embodiment.

In the EMI filter according to the embodiment in FIG. 8, illustration of a core unit is omitted, and only the configuration of coil units 120, 130, 120′, and 130′ is illustrated. The core unit may have a configuration similar to that shown in FIGS. 2 and 3, and therefore a duplicate description thereof will be omitted.

Referring to FIG. 8, a third coil unit 120′ and a fourth coil unit 130′ are disposed under a first coil unit 120 and a second coil unit 130. Here, the first coil unit 120 and the third coil unit 120′ have the same configuration as each other, and the third coil unit 120′ is disposed in a manner of being rotated by 180 degrees relative to the first coil unit 120 when viewed in a plan view. Similarly, the first coil unit 120 and the third coil unit 120′ have the same configuration as each other, and the third coil unit 120′ is disposed in a manner of being rotated by 180 degrees relative to the first coil unit 120 when viewed in a plan view.

Accordingly, one end of a conductive pattern constituting each of the first coil unit 120 and the second coil unit 130 is led out to one side in the third direction, and one end of a conductive pattern constituting each of the third coil unit 120′ and the fourth coil unit 130′ is led out to the opposite side in the third direction.

In addition to the EMI filter having the above-described configuration, it will be apparent to those skilled in the art that a transformer may also be constituted using a PCB-type coil formed in such a manner that conductive patterns having the same planar shape as each other are disposed on and under a substrate and are conductively connected to each other through a plurality of via holes.

While the present disclosure has been particularly shown and described with reference to exemplary embodiments thereof, these embodiments are only proposed for illustrative purposes and do not restrict the present disclosure, and it will be apparent to those skilled in the art that various changes in form and detail may be made without departing from the essential characteristics of the embodiments set forth herein. For example, respective configurations set forth in the embodiments may be modified and applied. Further, differences in such modifications and applications should be construed as falling within the scope of the present disclosure as defined by the appended claims.

1. A magnetic coupling device, comprising:
a core unit comprising an upper core and a lower core; and
a coil unit partially disposed inside the core unit, the coil unit comprising a first coil unit and a second coil unit,
wherein the first coil unit comprises a first substrate, a first upper conductive pattern disposed on an upper surface of the first substrate, and a first lower conductive pattern disposed on a lower surface of the first substrate,
wherein the second coil unit comprises a second substrate, a second upper conductive pattern disposed on an upper surface of the second substrate, and a second lower conductive pattern disposed on a lower surface of the second substrate,
wherein each of the first upper conductive pattern and the first lower conductive pattern has a first spiral planar pattern,
wherein each of the second upper conductive pattern and the second lower conductive pattern has a second spiral planar pattern, and
wherein the first upper conductive pattern and the first lower conductive pattern are conductively connected to each other through a plurality of first via holes penetrating the first substrate in a vertical direction and disposed in an extension direction of each of the first upper conductive pattern and the first lower conductive pattern.

2. The magnetic coupling device according to claim 1, wherein the coil unit comprises:
a turn portion in which each of the first upper conductive pattern, the first lower conductive pattern, the second upper conductive pattern, and the second lower conductive pattern forms a plurality of turns; and
a pattern lead-out portion in which one end of each of the first upper conductive pattern, the first lower conductive pattern, the second upper conductive pattern, and the second lower conductive pattern is led out from the turn portion, the pattern lead-out portion being disposed on one side of the turn portion.

3. The magnetic coupling device according to claim 2, wherein opposite ends of the first upper conductive pattern, the first lower conductive pattern, the second upper conductive pattern, and the second lower conductive pattern are conductively connected to each other, the opposite ends being disposed at an innermost position in the turn portion.

4. The magnetic coupling device according to claim 2, wherein the second upper conductive pattern and the second lower conductive pattern are conductively connected to each other through a plurality of second via holes penetrating the second substrate in the vertical direction and disposed in an extension direction of each of the second upper conductive pattern and the second lower conductive pattern.

5. The magnetic coupling device according to claim 4, wherein the turn portion comprises:
a central portion wrapped by the core unit; and
outer portions disposed on both sides of the central portion, and
wherein, among the plurality of first via holes and the plurality of second via holes, a number of via holes per unit length in the central portion is greater than a number of via holes per unit length in the outer portions.

6. The magnetic coupling device according to claim 4, wherein the plurality of second via holes is disposed in the turn portion in an extension direction of the second spiral pattern at an interval corresponding to ⅒ or less of a length of the second upper conductive pattern in a long-axis direction of the turn portion.

7. The magnetic coupling device according to claim 4, wherein the plurality of second via holes is disposed in the turn portion in an extension direction of the second spiral pattern at an interval corresponding to 1/20 or less of a length of the second upper conductive pattern in a long-axis direction of the turn portion.

8. The magnetic coupling device according to claim 4, wherein the plurality of first via holes and the plurality of second via holes have radial planar shapes in a manner of being aligned in a centrifugal direction from a center leg of the core unit.

9. The magnetic coupling device according to claim 1, wherein the first spiral planar pattern extends in a manner of circling in a first circling direction when viewed in a plan view, and
wherein the second spiral planar pattern extends in a manner of circling in a second circling direction when viewed in a plan view, the second circling direction being different from the first circling direction.

10. A circuit board, comprising:
a substrate; and
a magnetic coupling device disposed on the substrate,
wherein the magnetic coupling device comprises:
a core unit comprising an upper core and a lower core; and
a coil unit partially disposed inside the core unit, the coil unit comprising a first coil unit and a second coil unit,
wherein the first coil unit comprises a first substrate, a first upper conductive pattern disposed on an upper surface of the first substrate, and a first lower conductive pattern disposed on a lower surface of the first substrate,
wherein the second coil unit comprises a second substrate, a second upper conductive pattern disposed on an upper surface of the second substrate, and a second lower conductive pattern disposed on a lower surface of the second substrate,
wherein each of the first upper conductive pattern and the first lower conductive pattern has a first spiral planar pattern,
wherein each of the second upper conductive pattern and the second lower conductive pattern has a second spiral planar pattern, and
wherein the first upper conductive pattern and the first lower conductive pattern are conductively connected to each other through a plurality of first via holes penetrating the first substrate in a vertical direction and disposed in an extension direction of each of the first upper conductive pattern and the first lower conductive pattern.

11. The magnetic coupling device according to claim 1, wherein when viewed in a plan view, the first coil unit and the second coil unit are aligned with each other around first through-hole and second through-hole which center legs of the core unit passes through.

12. The magnetic coupling device according to claim 1, wherein the first upper conductive pattern and the first lower conductive pattern have the same planar shape as each other.

13. The magnetic coupling device according to claim 12, wherein a direction in which the first spiral planar pattern of the first upper conductive pattern circles is the same as a direction in which the first spiral planar pattern of the first lower conductive pattern circles.

14. The magnetic coupling device according to claim 1, wherein one end of the first upper conductive pattern is disposed on an edge portion of the first substrate, and other end of the first upper conductive pattern is disposed at an innermost position in the first spiral planar pattern.

15. The magnetic coupling device according to claim 1, wherein the second upper conductive pattern and the second lower conductive pattern have the same planar shape as each other.

16. The magnetic coupling device according to claim 15, wherein a direction in which the second spiral planar pattern of the second upper conductive pattern circles is the same as a direction in which the second spiral planar pattern of the second lower conductive pattern circles.

17. The magnetic coupling device according to claim 1, wherein one end of the second upper conductive pattern is disposed on an edge portion of the second substrate, and other end of the second upper conductive pattern is disposed at an innermost position in the second spiral planar pattern.

18. The magnetic coupling device according to claim 1, wherein ends of the second upper conductive pattern and the second lower conductive pattern are input terminals of current and ends of the first upper conductive pattern and the first lower conductive pattern are output terminals of current.

19. The magnetic coupling device according to claim 4, wherein the plurality of first via holes or the plurality of second via holes includes via holes having at least one type of a single via hole or a via hole group.

20. The magnetic coupling device according to claim 19, wherein the first coil unit or the second coil unit comprises:
a center portion;
both side potions in which the extension direction is changed; and
a first portion disposed between the center portion and the both side portions,
wherein the via hole groups are disposed in the center portion, the both side portions, and the first portion, and
wherein at least one single via hole is disposed between two adjacent ones of the via hole groups.
